(19) United States
(12) Patent Application Publication
(10) Pub. No.: US 2005/0127994 A1
(43) Pub. Date: Jun. 16, 2005

(54) Wireless Output Chip With Power Detector And Related Manufacturing Method

(76) Inventor: Chun-Hsueh Chu, Taipei City (TW)

Correspondence Address: NORTH AMERICA INTERNATIONAL PATENT OFFICE (NAIPC), P.O. BOX 506, MERRIFIELD, VA, 22116, US

(21) Appl. No.: 10/710,156

(22) Filed: Jun. 22, 2004

(30) Foreign Application Priority Data
Dec. 16, 2003 (TW) 092135562

(51) Int. Cl. H03G 3/20

(52) U.S. Cl. 330/140

(57) ABSTRACT

Wireless output chip with a power detector and related manufacturing method. A BiCMOS process is used to integrate a power amplifier and a power detector, which detects power outputted by the power amplifier, into one chip. The power amplifier including bipolar junction transistors is formed by using BJT forming procedures in the BiCMOS process. The power detector includes a charging unit of a capacitor, a controlled current source and a reference current source constructed by metal-oxide-semiconductor transistors formed by MOS forming procedures in the BiCMOS process. Thus, the power detector and the power amplifier can be integrated into one chip using the low-cost BiCMOS process.

### BACKGROUND OF INVENTION

1. Field of the Invention

The present invention relates to a radio frequency output chip with a power detector and related manufacturing method, and more specifically, to an output chip with a power detector and related manufacturing method by using a BiCMOS process to integrate a power detector and a power amplifier into one chip.

2. Description of the Prior Art

In modern society, all kinds of knowledge, information and data can be rapidly transmitted and interchanged via the Internet. The development of the wireless local area network (WLAN) further enables persons to access information from the Internet without using transmission lines. Additionally, hardware circuits such as an output chip for performing power amplification are always required to receive or access information from the Internet. Therefore, it is an important issue to reduce a production cost of the related hardware circuits for helping the Internet to become less expensive and more popular.

Please refer to FIG. 1. FIG. 1 is a block diagram of a conventional network circuit having a power amplifier chip and a power detector chip for transmitting signals. As shown in FIG. 1, a network circuit 10 such as a network interface card of a wireless network includes an access circuit 12 for controlling the network circuit 10, a power amplifier chip 14, a power detector chip 18, a power control circuit 19, and an antenna 16 for sending signals to the wireless network. Additionally, when a signal is transmitted from the network circuit 10 to the wireless network, the signal will be firstly wrapped, coded and modulated by the access circuit 12 to become an input signal Sip of the power amplifier chip 14. Then, the power amplifier chip 14 performs power amplification on the input signal Sip and outputs an output signal Sop, which is a radio frequency (RF) signal, to the antenna 16. Finally, the output signal Sop is sent to the wireless network by the antenna 16.

The power amplifier chip 14 has to perform the power amplification regularly and steadily so that the network circuit 10 can send a signal having uniform power to the wireless network. However, the power amplifier chip 14 may work unstably and may output the output signal Sop with power that is too large or too small due to several reasons. For example, shifts in temperature or undesirable factors in a manufacturing process may result in degrading performances of the power amplifier chip 14, which causes the power amplifier chip 14 to work abnormally. For preventing the above-mentioned drawback, an output signal Sop2, which is a portion of the output signal Sop output by the power amplifier chip 14, is input into the power detector chip 18. Thereafter, the power detector chip 18 detects power of the output signal Sop2 and outputs a corresponding detection signal Vpd as a detection result. Subsequently, the detection signal Vpd is transmitted to the power control circuit 19, which can perform a feedback control on the power amplifier chip 14 according to the detection signal Vpd. For example, when the power of the output signal Sop is above a normal level such that the power of the output signal Sop2 is also above the normal level, the power detector chip 18 will output the detection signal Vpd to respond to such abnormal condition. Then, the power control circuit 19 modifies the operation of the power amplifier chip 14 for reducing an extent of the power amplification so that the power of the output signal Sop can be returned to the normal level. For example, the power control circuit 19 may change a bias voltage of the power amplifier chip 14 for reducing the extent of the power amplification.

As shown in FIG. 1, the conventional power detector chip includes a diode Dp, a resistor Rp and a capacitor Cp, and basically functions as a peak holder to keep track of peak values of the AC output signal Sop2 and generate the corresponding detection signal Vpd, such that the detection signal Sop2 is nearly a DC voltage with amplitude approximately equal to peak values of the AC output signal Sop2. That is, the detection signal Vpd represents amplitude of the output signal Sop2, so that the detection signal Vpd can represent the power of the output signal Sop since the amplitude of the output signal Sop corresponds to the power of the output signal Sop2. Please refer to FIG. 2. FIG. 2 is a timing diagram of related signals corresponding to an operation of the power detector chip shown in FIG. 1. As shown in FIG. 2, an x-axis represents time while a y-axis represents values of the signals. When a voltage of the input signal Sop2 is larger than a voltage of the detection signal Vpd and is large enough to turn on the diode Dp, the capacitor Cp is charged to store charges. Then, when a waveform of the output signal Sop2 reaches its peak and starts to fall from the peak, the capacitor Cp discharges slowly via the resistor Rp for approximately keeping the voltage of the detection signal Vpd at a value of the peak so that the voltage of the detection signal Vpd can be used to represent the power of the output signal Sop2 (and Sop).

Generally, the power amplifier chip 14 and the power detector chip 18 are two different chips that are separately manufactured and packaged, and the power amplifier chip 14 and the power detector chip 18 are assembled together in a circuit board of the network circuit 10. However, since the conventional method for manufacturing the network circuit 10 has a high cost, it is hard to make the network circuit 10 become popular. Additionally, the production cost cannot be reduced even though a power detector circuit and a power amplifier circuit can be integrated in the same chip. Due to physical characteristics of transistors, the power amplifier circuit usually comprises a bipolar junction transistor (BJT) so that a BJT forming process, such as a GaAs BJT forming process, is usually used to manufacture the power amplifier circuit. While the power detector circuit and the power amplifier circuit are integrated in the same chip, the production cost cannot be reduced when the power detector circuit and the power amplifier circuit are both manufactured by the GaAs BJT forming process, since the GaAs BJT forming process costs quite high. Additionally, while the power detector circuit and the power amplifier circuit are integrated in the same chip, the production cost still cannot be reduced when the power detector circuit is manufactured by a metal oxide semiconductor (MOS) forming process and the power amplifier circuit is manufactured by the GaAs BJT forming process since the costs for integrating the GaAs BJT forming process costs with the MOS forming process are high.

### SUMMARY OF INVENTION

It is therefore a primary objective of the claimed invention to provide an output chip with a power detector and related manufacturing method by using a BiCMOS process to integrate a power detector and a power amplifier into one chip for solving the above-mentioned problems and reducing a production cost of the output chip.

According to the claimed invention, a power detector manufactured by a MOS forming procedure includes a controlled current source, a reference current source, and a capacitor for storing charges, and the power detector is capable of generating a detection signal according to power of an output signal output by a power amplifier. The controlled current source is used to provide a charging current corresponding to a voltage difference between the output signal and the detection signal. The reference current source is used to provide a reference current. The capacitor is charged by the charging current and the reference current and a voltage corresponding to charges stored in the capacitor can be used as the detection signal, which corresponds to the power of the output signal output by the power amplifier.

Since the power detector of the claimed invention comprises MOS transistors, the claimed invention can use a BiCMOS process to integrate the power amplifier and the power detector into one chip. Additionally, because the BiCMOS process is well developed and has low costs, a production cost of the claimed invention for integrating the power amplifier and the power detector into one chip can be reduced, thereby decreasing costs of a network circuit and making the network circuit become more popular.

These and other objectives of the claimed invention will no doubt become obvious to those of ordinary skill in the art after reading the following detailed description of the preferred embodiment, which is illustrated in the multiple figures and drawings.

### BRIEF DESCRIPTION OF DRAWINGS

FIG. 1 is a block diagram of a conventional network circuit having a power amplifier chip and a power detector chip for transmitting signals.

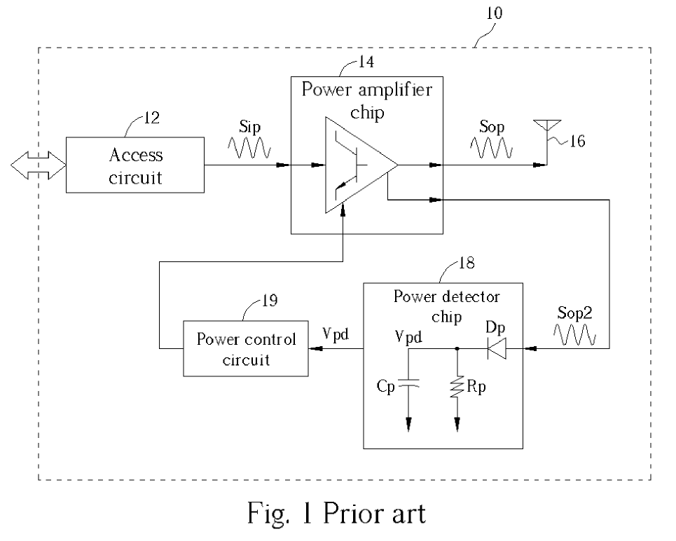

FIG. 2 is a timing diagram of related signals corresponding to an operation of the power detector chip shown in FIG. 1.

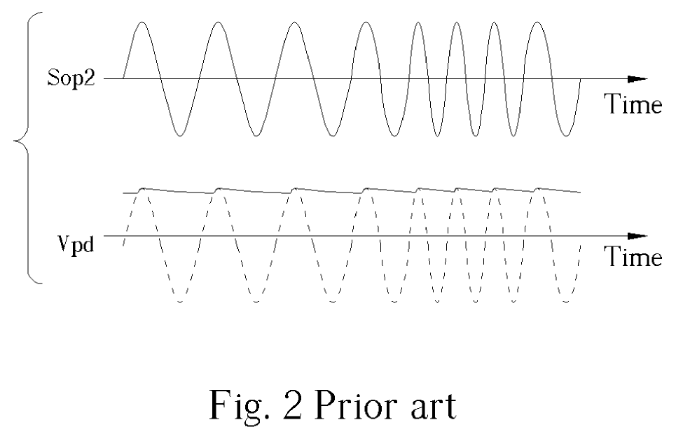

FIG. 3 is a block diagram of an output chip according to the present invention.

FIG. 4 is a circuit diagram of the power detector according to the present invention.

FIG. 5 is a diagram illustrating relationship between an input signal and an output signal of the power detector shown in FIG. 4.

### DETAILED DESCRIPTION

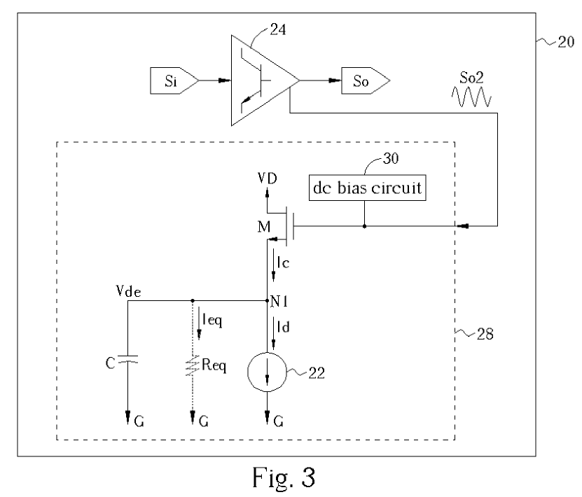

Please refer to FIG. 3. FIG. 3 is a block diagram of an output chip according to the present invention. As shown in FIG. 3, an output chip 20 can be used in a network circuit to perform power amplification on a signal such as a RF signal, which will be sent to a network such as a wireless network. Additionally, the output chip 20 includes a power amplifier 24 and a power detector 28. An input signal Si that will be transmitted to a network is input into the power amplifier 24, which performs the power amplification on the input signal Si and outputs an output signal So. Then, the output signal So is transmitted to an antenna (not shown in FIG. 3) and is sent to the network as an RF signal. At the same time, an output signal So2, which is a portion of the output signal So, is transmitted to the power detector 28, which detects power of the output signal So2 and generates a corresponding detection signal Vde whose signal level corresponds to the power of the output signal So2 and the power of the output signal So. As discussed above, a feedback control can be performed on the operation of the power amplifier 24 according to the detection signal Vde such that the power amplifier 24 can output the output signal So with normal power.

As shown in FIG. 3, the power detector 28 is biased between the DC voltage VD and ground G. Additionally, the power detector 28 includes a MOS transistor M functioning as a controlled current source, a reference current source 22, a DC bias circuit 30 and a capacitor functioning as a charging unit. A gate of the MOS transistor M is an input end for receiving the output signal So2, while a source of the MOS transistor M is a control end electrically connected to a node N1. According to a voltage difference between a drain and the source of the MOS transistor M, a current Ic functioning as a charging current flows from the drain to the source and injects into the node N1. The reference current source 22 electrically connected to the node N1 is a constant current source and generates a constant current Id. The capacitor C has an end, which is electrically connected to the node N1 and can be regarded as a voltage end. The capacitor C is charged/discharged by the current Ic and Id, and a voltage of the node N1 derived from charges accumulated in the capacitor C is regarded as a detection signal Vde. The DC bias circuit 30 is used for providing a DC bias to the gate of the MOS transistor M.

An operation of the power detector 28 is described as follows. While realizing the power detector 28, the reference current source 22 can be realized by one or more MOS transistors. Equivalently, due to an equivalent output impedance of the reference current source 22, a resistor Req exists between the two ends of the reference current source 22, as shown in FIG. 3. The MOS transistor in the reference current source 22 functioning as a current source and the transistor M are both biased to operate in a saturation region. When a signal level of the output signal So2 is zero, a gate bias for turning on the transistor M allows current (Id+Ieq) to flow from the drain to the source. Additionally, when the signal level of the output signal So2 rises upwards, the gate bias for turning on the transistor M is raised so that the current flowing from the drain to the source is increased to charge the capacitor C, thereby raising the voltage of the detection signal Vde. When the signal level of the output signal So2 is increased to a peak and starts to lower, the capacitor C is discharged slowly via the resistor Req and the voltage of the detection signal Vde is substantially held at a value of the peak so that the voltage of the detection signal Vde corresponds to the power of the output signal So2 and the power of the output signal So.

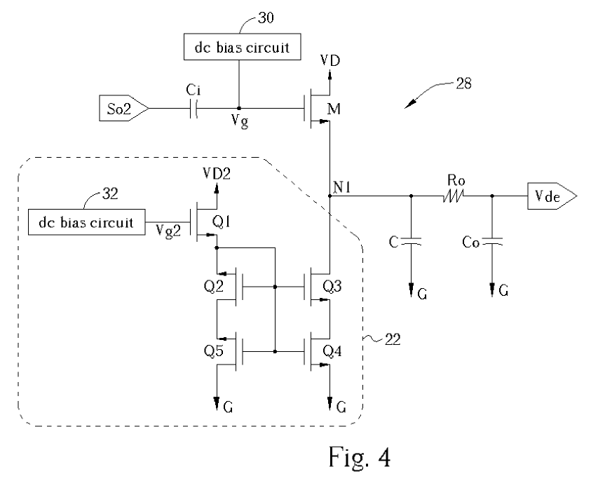

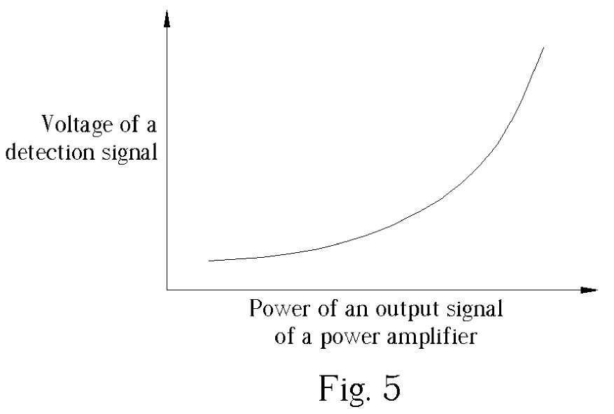

Please refer to FIG. 4. FIG. 4 is a circuit diagram of the power detector 28 according to the present invention. As shown in FIG. 3 and FIG. 4, the output signal So2 of the power amplifier 24 can be coupled to the transistor M via the capacitor Ci. The DC bias circuit 30 can be a divider comprising resistors for providing a DC bias Vg. The capacitor C functioning as a charging unit comprises a capacitor or a plurality of series capacitors. The detection signal Vde can be output through a transistor Ro and a capacitor Co. The reference current source 28 can be realized by nMOS transistors Q1-Q5, which form a current mirror biased between DC voltage VD2 and G. A gate of the transistor Q1 is biased at a bias voltage Vg2 provided by the DC bias circuit 32, which can be a divider comprising resistors. Please refer to FIG. 5. FIG. 5 is a diagram illustrating relationship between an input signal and an output signal of the power detector shown in FIG. 4. As shown in FIG. 5, an x-axis presents power of the output signal of the power amplifier 24 where the power of the output signal of the power amplifier 24 is usually expressed in dBm, while a y-axis presents a voltage of the detection signal Vde and the voltage of the detection signal Vde is expressed in volts. Additionally, the voltage of the detection signal is changed when the power of the output signal of the power amplifier 24 is changed. A feedback control can be performed on the power amplifier 24 according to the detection signal Vde so that the power amplifier 24 can stably output the output signal with uniform power.

Since the power detector of the present invention mainly comprises MOS transistors and the power amplifier mainly comprises bipolar junction transistors, the power detector and the power amplifier can be integrated in the same output chip by using a BiCMOS process. Additionally, because a MOS transistor and a bipolar transistor both can be manufactured in the BiCMOS process, the present invention can utilize only one process to manufacture the power detector and the power amplifier in the same output chip, thereby decreasing production costs of the output chip. Furthermore, a BJT forming procedure in the BiCMOS process is utilized to form the power amplifier, and a MOS forming procedure in the BiCMOS process is utilized to form the power detector. In the preferred embodiment of the present invention, a SiGe BiCMOS process can be utilized to manufacture the output chip and the power amplifier can be manufactured by use of hetero-junction bipolar transistor (HBT) forming procedure. After the output chip 20 is tested practically, the output chip 20 manufactured by the BiCMOS process according to the present invention has a good performance. Regarding the power detector 28, when the output power of the power amplifier is varied between 0 dBm and 18 dBm, the voltage of the detection signal Vde is correspondingly varied between 0.45 volts and 1.2 volts for presenting the power of the output signal of the power amplifier. In addition, a response time of the power detector is about 0.1 μs.

In comparison with the prior art, the power detector of the present invention comprises MOS transistors so that the present invention can use a BiCMOS process to integrate the power amplifier and the power detector into one chip, thereby reducing costs of the output chip and the network circuit. Additionally, since the power detector can be used to perform a feedback control, quality of network communication can be improved, thus making the network circuit become more popular.

Those skilled in the art will readily observe that numerous modifications and alterations of the device may be made while retaining the teachings of the invention. Accordingly, the above disclosure should be construed as limited only by the metes and bound of the appended claims.

1. An output chip comprising:
a power amplifier capable of performing power amplification of an input signal to generate a corresponding output signal and providing a secondary output signal according to the output signal; and
a power detector capable of generating a detection signal according to the secondary output signal such that a signal level of the detection signal corresponds to an average power of the output signal, the power detector comprising:
a controlled current source having an input end electrically connected to the power amplifier for receiving the secondary output signal and a control end, the controlled current source capable of providing a charging current corresponding to a signal difference between the input end and the control end;
a reference current source for providing a reference current; and
a charging unit having a voltage end electrically connected to the control end, the charging unit capable of storing charges provided by the charging current and the reference current and outputting the detection signal from the voltage end such that a signal level of the detection signal corresponds to the charges stored in the charging unit.

2. The output chip of claim 1 wherein the controlled current source is a metal oxide semiconductor (MOS) transistor, the input end is a gate of the MOS transistor, and the control end is a source of the MOS transistor.

3. The output chip of claim 1 wherein the reference current source comprises at least one MOS transistor.

4. The output chip of claim 1 wherein the charging unit comprises at least one capacitor.

5. The output chip of claim 1 wherein the output signal is a radio frequency (RF) signal.

6. The output chip of claim 1 wherein the power amplifier comprises at least one bipolar junction transistor (BJT).

7. The output chip of claim 1 wherein the power amplifier and the power detector are formed in a BiCMOS process.

8. A method of manufacturing an output chip comprising:
utilizing a BiCMOS process to form a power amplifier, the power amplifier capable of performing power amplification of an input signal to generate a corresponding output signal and providing a secondary output signal according to the output signal; and
while forming the power amplifier, performing a second procedure in the BiCMOS process to form a power detector, the second procedure comprising:
forming a controlled current source having an input end electrically connected to the power amplifier for receiving the secondary output signal and a control end, the controlled current source capable of providing a charging current corresponding to a signal difference between the input end and the control end;
forming a reference current source for providing a reference current; and
forming a charging unit having a voltage end electrically connected to the control end, the charging unit capable of storing charges provided by the charging current and the reference current and outputting the detection signal from the voltage end such that a signal level of the detection signal corresponds to the charges stored in the charging unit.

9. The method of claim 8 wherein a MOS forming procedure in the BiCMOS process is utilized to form the controlled current source such that the input end is a gate of a MOS transistor and the control end is a source of the MOS transistor.

10. The method of claim 8 wherein a MOS forming procedure in the BiCMOS process is utilized to form the reference current source.

11. The method of claim 8 wherein at least one capacitor is formed as the charging unit while the second procedure is performed.

12. The method of claim 8 wherein the output signal is a RF signal.

13. The method of claim 8 wherein a BJT forming procedure in the BiCMOS process is utilized to form the power amplifier.

14. The method of claim 8 wherein the BiCMOS process is a SiGe BiCMOS process.
